(19) United States
(12) Patent Application Publication
(10) Pub. No.: US 2025/0374739 A1
(43) Pub. Date: Dec. 4, 2025

(54) MULTI-LAYER MICRO-LED DISPLAY AND METHOD OF FABRICATION FOR PANEL LEVEL INTEGRATION

(71) Applicant: HYPERLUME INC., Toronto (CA)

(72) Inventors: MOHSEN ASAD, OTTAWA (CA); HOSSEIN FARIBORZI, AUBURNDALE, MA (US)

(73) Assignee: HYPERLUME INC., OTTAWA, ON (CA)

(21) Appl. No.: 18/707,685

(22) PCT Filed: Nov. 4, 2022
(86) PCT No.: PCT/US2022/048990

§ 371 Date: May 6, 2024

(51) Int. Cl. H10H 29/85; H01L 25/16; H10H 29/01; H10H 29/03; H10H 29/80

(52) U.S. Cl. CPC H10H 29/857; H01L 25/167; H10H 29/03; H10H 29/0364; H10H 29/962

(57) ABSTRACT

A multi-layer display including an upper substrate including light emitting diodes (LEDs) fabricated on a topside of the upper substrate, and LED bonding pads fabricated on a bottomside of the upper substrate. The LED bonding pads being electrically connected to the LEDs through vias extending through the upper substrate. The display also including a lower substrate including LED driver circuits and driver bonding pads fabricated on a topside of the lower substrate. The driver bonding pads being electrically connected to the LED driver circuits, where the LED bonding pads and driver bonding pads are aligned and electrically connected to each other, thereby electrically connecting the LED driver circuits to the LEDs.

### FIELD

A multi-layer micro-LED display and method of fabrication for panel-level integration.

### BACKGROUND

Conventional micro-LED displays may include light-emitting diodes (LEDs) and driving integrated circuits (IC) assembled together on the topside of a common panel. These conventional configurations, however, result in lower fabrication throughput due to increased manufacturing time, a complex repair process, and an unwanted bezel around the perimeter of the resultant device.

### SUMMARY

An example embodiment includes a multi-layer display including an upper substrate including light emitting diodes (LEDs) fabricated on a topside of the upper substrate, and LED bonding pads fabricated on a bottom side of the upper substrate. The LED bonding pads being electrically connected to the LEDs through vias extending through the upper substrate. The display also includes a lower substrate including LED driver circuits and driver bonding pads fabricated on a topside of the lower substrate. The driver bonding pads being electrically connected to the LED driver circuits, where the LED bonding pads and driver bonding pads are aligned and electrically connected to each other, thereby electrically connecting the LED driver circuits to the LEDs.

An example embodiment includes a method of manufacturing a multi-layer display. The method includes fabricating the light-emitting diodes (LEDs) on a topside of an upper substrate; fabricating LED bonding pads on a bottom side of the upper substrate, fabricating vias through the upper substrate, the vias electrically connecting the LED bonding pads to the LEDs, fabricating LED driver circuits and driver bonding pads on a topside of a lower substrate. The driver bonding pads are electrically connected to the LED driver circuits. The method also includes temporarily connecting the LED bonding pads to a test circuit and confirming the operation of the LEDs, removing the LED bonding pads from the test circuit when the operation of the LEDs is confirmed, and aligning and electrically connecting the LED bonding pads to the driver bonding pads, thereby electrically connecting the LED driver circuits to the LEDs.

An example embodiment includes a multi-layer display including an upper substrate including light emitting diodes (LEDs) fabricated on a topside of the upper substrate, LED bonding pads fabricated on the bottom side of the upper substrate, and vias extending through the upper substrate and electrically connecting the LEDs to the LED bonding pads. The LED bonding pads are aligned with driver bonding pads of a lower substrate including LED driver circuits, to facilitate the electrical connection of LEDs to the LED driver circuits.

An example embodiment includes a method of manufacturing a multi-layer display. The method includes fabricating light emitting diodes (LEDs) on a topside of an upper substrate, fabricating LED bonding pads on a bottom side of the upper substrate, fabricating vias extending through the upper substrate, and electrically connecting the LEDs to the LED bonding pads. The LED bonding pads are fabricated to align with driver bonding pads of a lower substrate including LED driver circuits, to facilitate the electrical connection of LEDs to the LED driver circuits.

An example embodiment includes a multi-layer display including a substrate including a topside and a bottomside opposite the topside, light emitting diodes (LEDs) fabricated on a topside of the substrate, LED driving circuits fabricated on a bottomside of the substrate, and through vias extending through the substrate and electrically connecting the LEDs to the driving circuits.

An example embodiment includes a method of manufacturing a multi-layer display. The method includes fabricating light-emitting diodes (LEDs) on a topside of the substrate, fabricating LED driving circuits on a bottomside of the substrate opposite the topside of the substrate, and fabricating through vias extending from the topside of the substrate to the bottomside of the substrate to electrically connect the LEDs to the driving circuits.

### BRIEF DESCRIPTION OF THE DRAWINGS

So that the manner in which the above recited features of the present disclosure can be understood in detail, a more particular description of the disclosure, briefly summarized above, may be had by reference to example embodiments, some of which are illustrated in the appended drawings. It is to be noted, however, that the appended drawings illustrate only example embodiments of this disclosure and are therefore not to be considered limiting of its scope, for the disclosure may admit to other equally effective example embodiments.

FIG. 1 is a display system including multiple semiconductor-based micro-LEDs, row drivers, column drivers, control ICs, power units and other micro-devices, according to an example embodiment of the present disclosure.

FIG. 2 is a display system including micro-ICs, micro-LEDs, and other micro-devices, according to an example embodiment of the present disclosure.

FIG. 3 is a display system including a sensor integrated (e.g. fabricated) on topside (or backside) of the display or with corresponding drivers, according to an example embodiment of the present disclosure.

FIG. 4 is a display system with a sensor integrated on the topside or backside of the display where the driving/read-out circuit is also integrated on the topside or backside of the display, according to an example embodiment of the present disclosure.

FIG. 5 is a display system with a camera such as an image sensor and other sensors incorporated into the display panel, according to an example embodiment of the present disclosure.

FIG. 6 is a micro-LED display system with micro-ICs and row/column lines that are connected to the pads and through substrate such as glass/polymer/ . . . ) vias close to the edge of the display, according to an example embodiment of the present disclosure.

FIG. 7 is a multilayer display system where the emission layer including micro-LEDs with or without micro-ICs and row/column drivers are located on different layers such as different sides of substrate/panel and are connected through conductive vias, according to an example embodiment of the present disclosure.

FIG. 8 is the emission layer of the display that includes the micro-LEDs, sensors and micro-ICs, according to an example embodiment of the present disclosure.

FIG. 9 is a bezel-free display including an array of micro-LEDs and micro-ICs that are located over the emission substrate and connected to the driving system using interconnect vias, according to an example embodiment of the present disclosure.

FIG. 10 is a bezel-free display system including micro-LEDs (micro-ICs) and driving circuits fabricated on separate substrates, according to an example embodiment of the present disclosure.

FIG. 11 is a bezel-free multi-layer display system with modular driving circuits distributed on another substrate, according to an example embodiment of the present disclosure.

FIG. 12 is a multi-layer display system before assembling the layers together, according to an example embodiment of the present disclosure.

FIG. 13 is a multi-layer display system after the layers are connected electrically and mechanically together, according to an example embodiment of the present disclosure.

FIG. 14 is a multi-layer display where the driving layer substrate (e.g. carrier) is removable using a physical or chemical lift-off process to provide lower weight and flexibility, according to an example embodiment of the present disclosure.

FIG. 15 is a multi-layer bezel-free display where micro-LEDs and driving ICs are located on a different substrate and are connected through conductive vias, according to an example embodiment of the present disclosure.

FIG. 16 is the multi-layer display system before the micro-devices the micro-LEDs layer is connected to the micro-IC layer using conducting through vias, according to an example embodiment of the present disclosure.

FIG. 17 is the multi-layer display system after the micro-devices the micro-LEDs layer is connected to the micro-IC layer using conducting through vias, according to an example embodiment of the present disclosure.

FIG. 18 is the multi-layer display system where the substrate with the micro-ICs thereon are removable with a physical or chemical process, according to an example embodiment of the present disclosure.

FIG. 19 is the multi-layer display system where the micro-LEDs and micro-ICs are fabricated on different substrates, according to an example embodiment of the present disclosure.

FIG. 20 multi-layer micro-LED system where the bottom substrate is removable using physical or chemical lift-off process to provide lower weight and flexibility, according to an example embodiment of the present disclosure.

FIG. 21 is a multi-layer micro-LED system where micro-devices are connectable to a CMOS driving circuit using conductive through vias, according to an example embodiment of the present disclosure

FIG. 22 is a test set-up where micro-devices such as micro-LEDs are assembled on a substrate with conductive vias, a probe card is used to illuminate the micro-devices and the optical intensity is measured to identify any non-functional micro-LEDs, according to an example embodiment of the present disclosure.

FIG. 23 shows a flowchart describing the manufacturing process of the micro-LED display.

FIG. 24 is a bezel-free passive driving display having micro-LEDs and a passive driver installed on different substrates or on other sides of a substrate, according to an example embodiment of the present disclosure.

FIG. 25 shows a micro-LED display with micro-LEDs integrated on the topside of the substrate and driving micro-ICs integrated on the backside of the same substrate, according to an example embodiment of the present disclosure.

FIG. 26 shows a double side panel level integration where the micro-devices are integrated on the topside of the panel using bonding pads and micro-ICs are connected to the backside of the panel using bonding pads, according to an example embodiment of the present disclosure.

FIG. 27 shows a flowchart describing the manufacturing process of the micro-LED display with micro-LEDs integrated on the topside of the substrate and driving micro-ICs integrated on the backside of the same substrate, according to an example embodiment of the present disclosure.

### DETAILED DESCRIPTION

Various example embodiments of the present disclosure will now be described in detail with reference to the drawings. It should be noted that the relative arrangement of the components and steps, the numerical expressions, and the numerical values set forth in these example embodiments do not limit the scope of the present disclosure unless it is specifically stated otherwise. The following description of at least one example embodiment is merely illustrative in nature and is in no way intended to limit the disclosure, its application, or its uses. Techniques, methods and apparatus as known by one of ordinary skill in the relevant art may not be discussed in detail but are intended to be part of the specification where appropriate. In all the examples illustrated and discussed herein, any specific values should be interpreted to be illustrative and non-limiting. Thus, other example embodiments could have different values. Notice that similar reference numerals and letters refer to similar items in the following figures, and thus once an item is defined in one figure, it is possible that it need not be further discussed for the following figures. Below, the example embodiments will be described with reference to the accompanying figures.

One object of the devices/methods of the present disclosure are to provide low-cost, fast and reliable technology to fabricate displays in a multi-layer panel structure. The disclosure is related to the heterogeneous integration of micro-devices such as micron-size light-emitting diode (micro-LEDs) and driving integrated circuits (micro-ICs) on separate panels and assembled together. This process/structure increases the speed of the transfer process and limits the need to use expensive fabrication tools that are used to transfer the micro-devices onto the substrate. In addition, after being transferred onto the substrate, the micro-devices may be tested electrically to ensure proper operation and make any potential repairs if needed. Specifically, in one example, micro-devices such as micro-LEDs may be the only elements on the substrate, and therefore the repair process may be more easily performed due to having access to the whole substrate. In addition, several sensors and other device technologies may also be integrated on the same substrate with (e.g. in between) the micro-LEDs. Since the connection between layers is performed through conductive vias, a bezel-free display is feasible to fabricate. In addition, integrating micro-devices and drivers on both sides of the substrate may provide a larger processable substrate and panel level integration which may increase the fabrication throughput. This process reduces the fabrication cost of the micro-LED display by testing the micro-LEDs before final assembly, separating the micro-LED process from the driving circuit and performing repairs if needed. As a result, any driving technology such as a complementary metal oxide semiconductor (CMOS) or thin film transistor (TFT) may be used. Several embedded sensors are yet another benefit of this packaging method.

The disclosed process is for manufacturing (e.g. fabricating) a structure that is a bezel-free multi-layer micro-LED display where the driving circuit and color-conversion may be integrated on separate layers of the substrate. The structure may be used for various applications such as optical communication and biomedical stimulation among others. As stated in this innovation, the micro-LEDs are transferred initially to a receiver substrate such as glass or polymer with permanent bonding. The substrate with micro-LEDs thereon may be any size (e.g. tiles) and is referred to herein as a micro-LED Mat. The Mat structure includes electrodes for micro-LEDs, driver circuits (micro-ICs) or other elements bonding, re-routing the driving and power lines, vias to connect backside and front side electrical components and pads on the edges or backside for testing and integration. All the micro-LEDs transferred permanently on the Mat may be tested to make sure they are optically and electrically functional. If required, any repair process may be performed on the Mat (without the need to repair the flat panel with the driving circuits). In other words, the Mat having the micro-LEDs is separate from the panel including the driving circuits, which allows the micro-LEDs to be tested/repaired separately before being joined with the driving circuits. The yielded (functional) micro-LED Mat may be integrated to the final substrate with the drivers using through glass vias (TGV), through polymer vias (TPV), from the edge contact or any via that supports electrical connections between the devices.

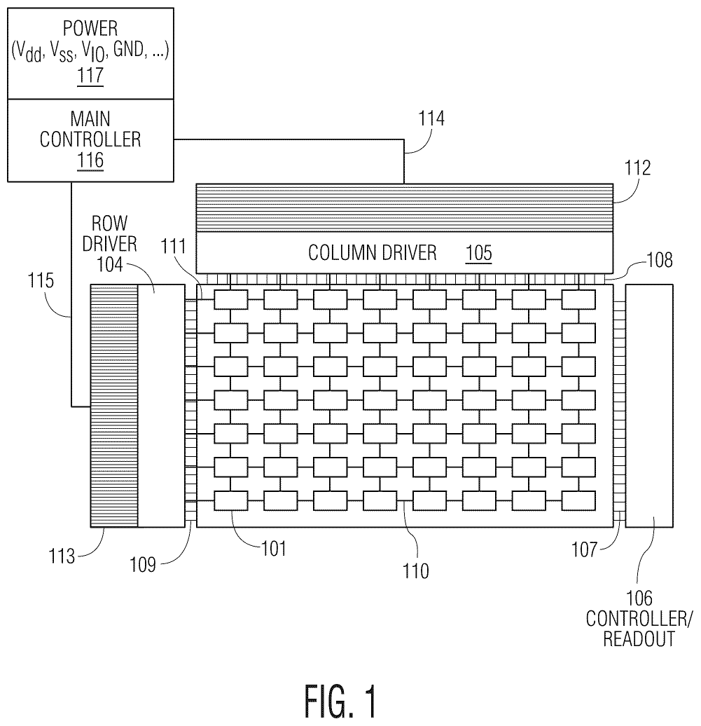

FIG. 1 shows an example of a display system including micro-LEDs 101 integrated onto a panel. Distribution lines 110 are also fabricated on the panel to deliver the power and driving information to the micro-LEDs 101. Row drivers 104 are connected to the panel using connection 109 and to the micro-LED arrays using conductive lines 111 on the panel. Column drivers 105 are connected to the micro-LEDs using connections 108 (e.g. a ribbon cable). Controller/readout circuit 106 may be connected to the display panel using connections 107 to provide further functionality in the driving system. This functionality includes, among others, driving the pixels, modifying the color uniformity, and repairing a dead pixel using a driving scheme. A power supply/controller 117 (e.g. device that produces various voltage levels V_{dd}, Vₛₛ, V_{ID}, GND, etc. for driving the display) and a main graphical driver/controller 116 (e.g. processor, memory, etc. for controlling the display) are also connected to the row and column drivers through connections 114 and 115. Parallel connections/shift registers 112 and 113 are used to distribute the driving information to the row and column drivers.

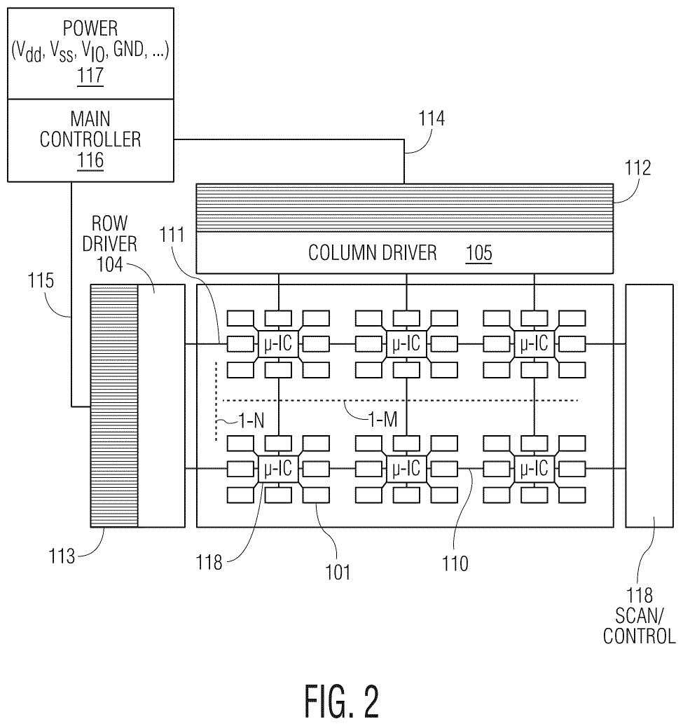

FIG. 2 is an example of a micro-LED display where the driving backplane is replaced with micro-ICs (μ-ICs) 118, and a group of micro-LEDs 101 are connected to each μ-IC 108. The μ-ICs drive a respective group of micro-LEDs 101, while the number of the μ-ICs (M×N) is generally defined according to the power delivery of each IC and the resolution of the display. Connections 111 (e.g. copper traces) are used to connect μ-ICs to the row/column driver or to the scan/control circuits 118. Micro-ICs 118 are controllers (e.g. processor, etc.) for controlling the operation of the micro-LEDs in the respective groups in response to instructions received from the main controller 116.

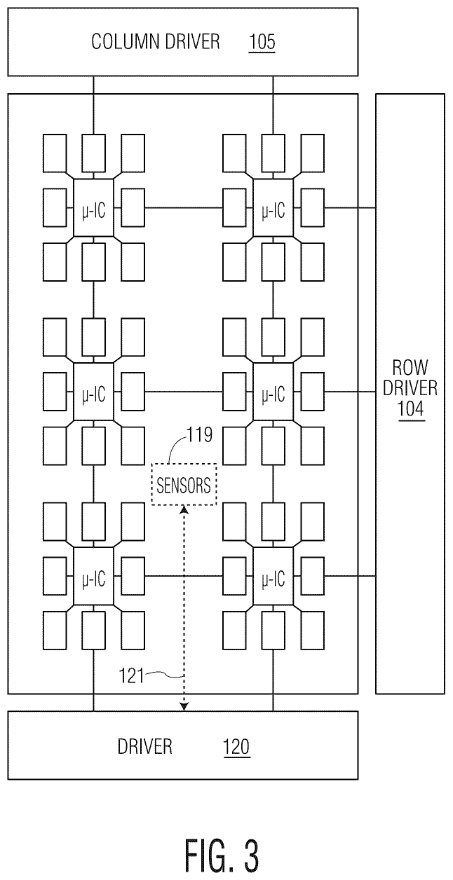

FIG. 3 shows another example of a micro-LED display including μ-ICs where a sensor system 119 such as a fingerprint sensor, optical sensor, or biosensor may be integrated into the panel. The sensors system may be fabricated/assembled to the topside of the panel between the micro-LEds or on the backside of the panel. Connection 121 may be used to connect the sensors to an external driver 120 for powering the sensor and collecting data from the sensor.

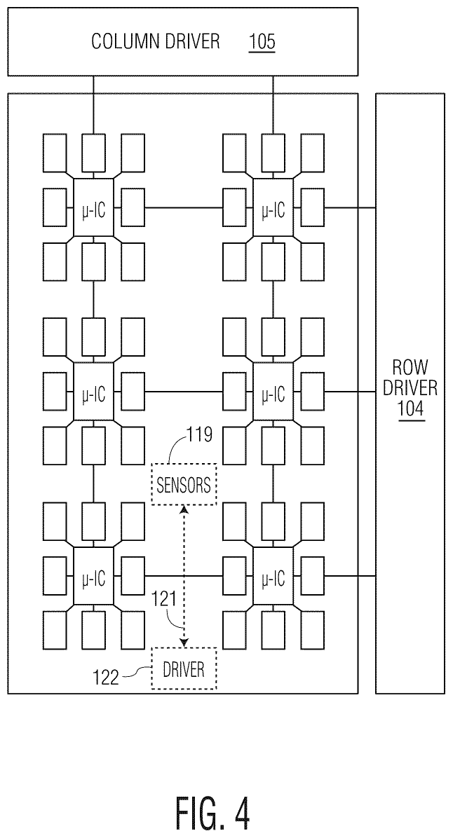

FIG. 4 shows an example of a micro-LED display including μ-ICs, sensors 119 and driver 122 both fabricated/assembled onto the panel. Both sensors 119 and driver 122 may be made or assembled to the panel frontside or backside as compared to the configuration in FIG. 3 where the sensor driver 120 is an external driver. A benefit to an internal driver is the reduced footprint of the overall device since the driver is positioned within the perimeter of the display.

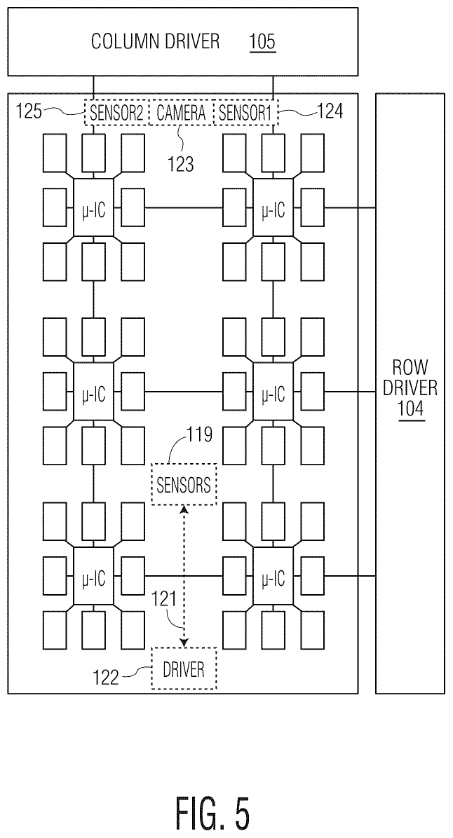

FIG. 5 shows an example of a micro-LED display including additional sensors 124 and 125 such as biosensors, optical sensors, laser scanners, and lidar sensors. These sensors are fabricated/integrated onto the frontside of the panel or the backside of the panel. A camera 123 may also be integrated to the display. Both the sensors and camera may be driven using outside driver circuits or internal drivers integrated onto the panel itself. This architecture may be beneficial for embedding sensors and cameras in the displays of mobile devices (e.g. smartphones), wearables (e.g. smart watches) and gaming devices (e.g. video game controllers) among others.

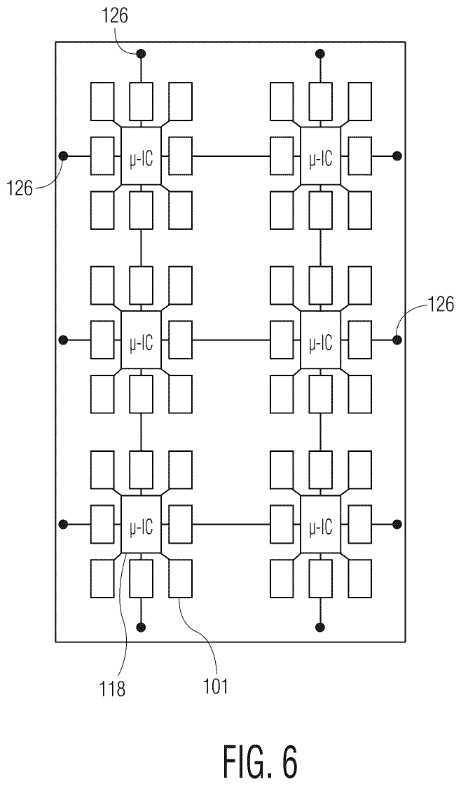

FIG. 6 shows an example of a micro-LED display panel including μ-ICs and conductive through vias 126 fabricated on the edge (e.g. perimeter) of the panel. Conductive through vias 126 electrically connect the topside of the panel to the backside and may be made from any conductive material such as copper. μ-ICs 118 are connected to the vias using conductive lines 110 or 111. The number of vias may correspond to the number of the μ-ICs in the rows and columns of the display panel.

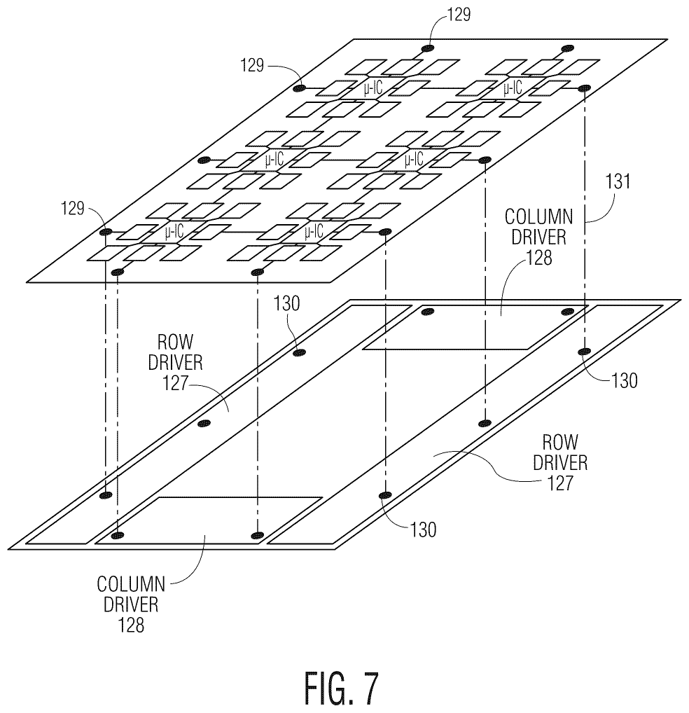

FIG. 7 shows an example of a multi-layer display system. μ-ICs and micro-LEDs are fabricated/assembled on the upper layer, while row drivers 127 and column drivers 128 are located on a lower layer. The μ-ICs and micro-LEDs are electrically connected to the drivers using conductive through vias 129 (e.g. through glass vias) and bonding pads 130 on the bottom layer. Vias 129 and the bonding pads 130 are fabricated to be aligned 131 together.

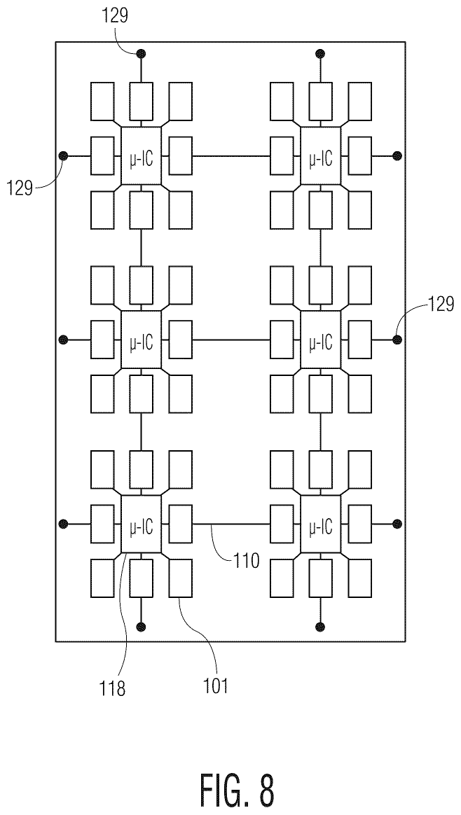

FIG. 8 shows an example of a micro-LED panel upper layer with μ-ICs 118, vias 129 at the edge of the substrate (e.g. on the perimeter of the substrate), and driving lines 110. With this structure, if the vias are fabricated at the edge of the display, according to the size/diameter of the vias, a bezel (unused portion) may result around the perimeter of the display. With the vias arranged in this manner, it would be difficult to achieve a bezel-free panel. The through vias shown in FIGS. 6-8 may be placed around the perimeter of the display to be connected to the perimeter placed drivers and/or wires/cables. This perimeter-based solution results in a bezel around the perimeter that increase the overall size of the display

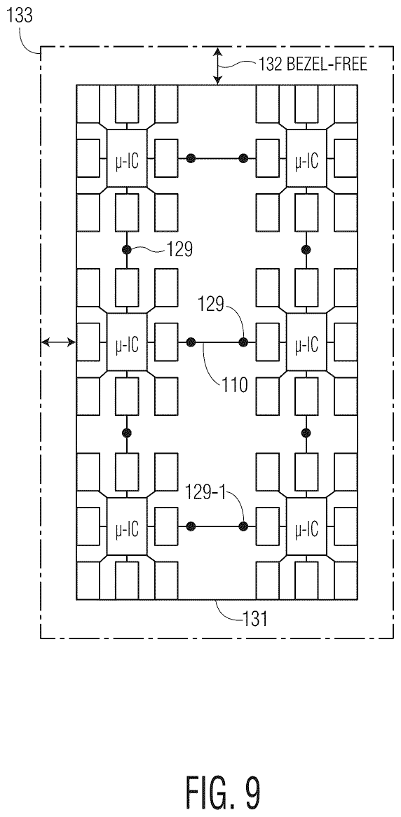

FIG. 9 shows an example of a solution to remove the bezel around the panel by relocating the vias 129 from the edge (e.g. perimeter) of panel 133 to the inner part of the panel. A bezel-free display 132 is shown where the edge 131 of the display is close to the micro-devices (micro-LEDs). Distribution of the vias may be flexibly designed to deliver the power and data to the micro-LEDs and μ-ICs.

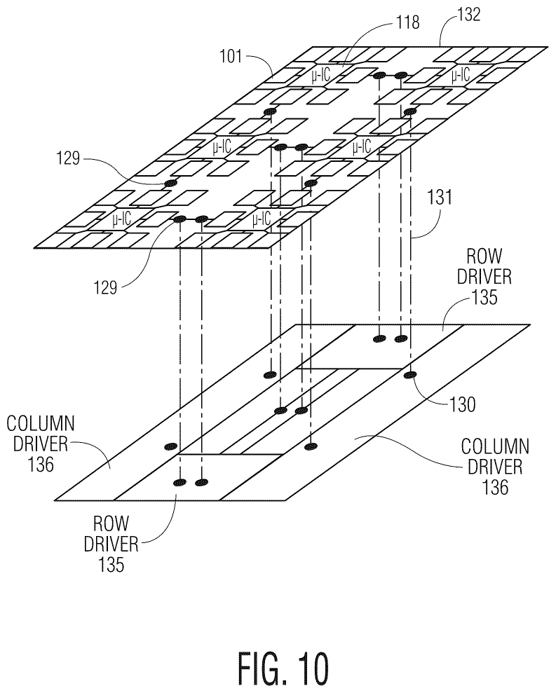

FIG. 10 shows an example of a bezel-free multi-layer micro-LED display where vias 129 are arranged towards the inner portion of the panel and away from display edge 132. Bonding pads 130 are aligned 131 with the vias and may be fabricated on the lower display layer which contains the row and column drivers. The bonding pads may be directly fabricated on the row/column drivers, or they may be fabricated on a bare area, and the electrical contact with the drivers may be made using redistribution lines.

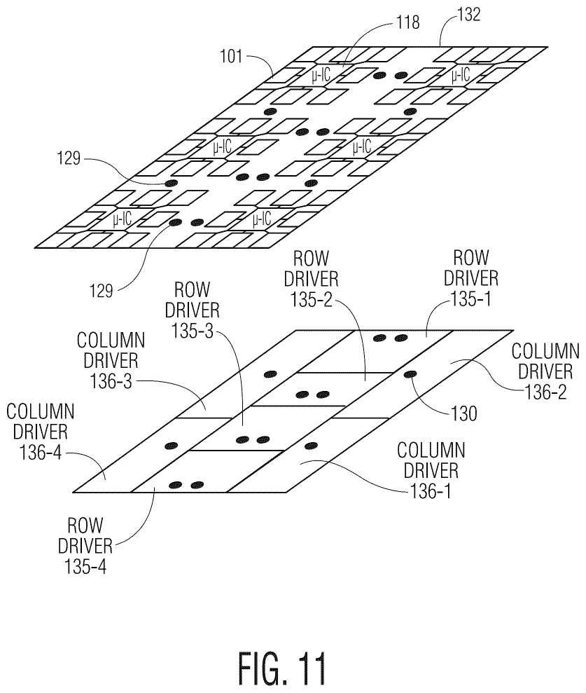

FIG. 11 shows an example of a multi-layer display with distributed row drivers 135-1, 135-2, 135-3, 135-4 and distributed column drivers 136-1, 136-2, 136-3, 136-4. Benefits for distributed row and column drivers include easier reparability, and the enabling of local programing the display for different brightness levels and refresh rates.

In the example embodiments shown in the previous figures and in the following figures, the placement of the micro-LEDs and micro-ICs are based on the desired dimensions and desired optical resolution of the final product (e.g. smartphone screen). Furthermore, the placement of internal devices such as display sensors, cameras, drivers and through vias may be determined based on the placement of the micro-LEDs and micro-ICs. For example, the internal devices (e.g. sensors, drivers, vias, etc.) are placed in vacant space between the micro-LEDs and micro-ICs where appropriate. The resulting product is a display screen with embedded functionality that is not visible to the user. In other words, the user will not be able to see the internal devices (e.g. sensors, drivers, vias, etc.) even though they are embedded in the screen. This ensures a seamless user experience.

The following figures show examples of portions of a multi-layer display where an upper panel (e.g. substrate) populated with LEDs may be bonded to a lower panel (e.g. substrate) populated with drivers. These portions show connections to a single micro-LED for illustration purposes. It is noted that a plurality of LEDs and possibly other devices such as sensors could be populated on the topside or bottomside of the upper substrate and a plurality of drivers could be populated on the lower substrate in order to produce the multiple LED and sensors structures shown throughout the figures. It is also noted that the upper substrate and lower substrate may be produced by the same manufacturer or different manufacturers. In the case where the upper and lower substrates are produced by different manufacturers, the manufacturers would share technical information to ensure that the specifications (e.g. number of drivers/LEDs, power requirements, connection point (e.g. pads/vias) locations are compatible. For example, a first manufacturer may produce the bottom substrate containing the drivers. The design of the bottom substrate may then be sent to a second manufacturer that designs the upper substrate (e.g. the display) having the LEDs and sensors. The second manufacturer would ensure that the design meets the LED/sensors requirements of the first manufacturer and that the bonding pads align with the bonding pads of the lower substrate.

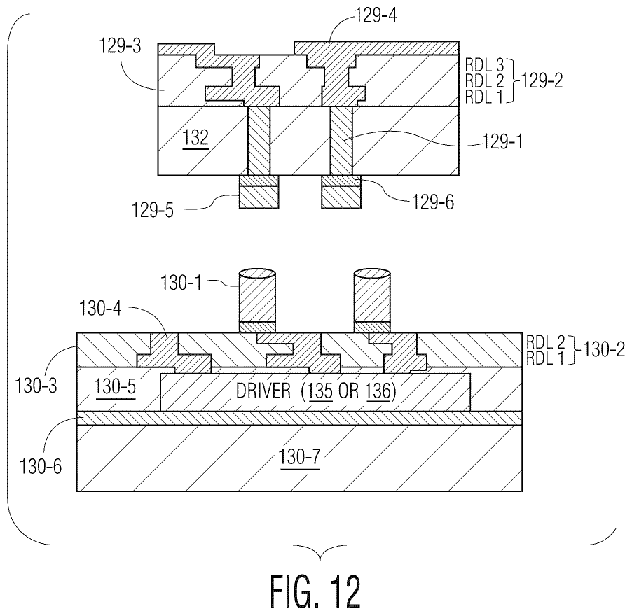

FIG. 12 shows an example of the structure for bonding a multi-layer display prior to integration of the upper/lower substrates. The upper substrate 132 may be made from silicon, glass, polymer, or any other insulator with specific optical and electrical properties. Conductive through substrate vias (e.g. through glass vias (TGV)) 129-1 are used to connect both sides of the substrate. Vias 129-1 may be made from a metallic material such as copper, highly doped semiconductor, or so on. There may be several metal layers 129-2 on the topside to redistribute the power or data. The redistributor layers (RDL) 129-2 may be made by plating, coating, patterning, or chemical mechanical polishing. Several dielectric layers 129-3 may be used for RDLs 129-2. Pads 129-4 may be for mounting the LEDs and/or sensors (not shown) to the topside of the display and may be electrically connected to the RDLs. The lower substrate 130-7 may be permanent or temporary and may be made from glass, silicon, polymer, or any other material. An additional layer 130-6, such as an adhesive, may be used to assemble the driver ICs 135 or 136 onto the substrate 130-7. Redistribution layers (RDL) 1302-2 may be used to distribute the power and driving information between different devices (e.g. from the drivers to the LEDs and sensors, etc.). The number of the RDLs depends on the driver architecture. RDLs are isolated using dielectrics 130-3 which may be made from semiconductor oxides, a polymer, or a photo-definable polymer. The driver ICs 135 or 136 may be embedded in a resin or polymer 130-5 for planarization, stronger placement, or several die stack placements. Bonding pad 130-1 may be created on the RDLs as for connecting to the upper display layer pads. The upper display pads may be made from a hard metal as a base metal 129-6 and another hard or soft metal or solder pad 129-5. Depending on the bonding technology, both soft and hard pads are feasible. For example, low-heat electrical bonding material (e.g. bonding cement) may be used to produce a thin display without damaging the substrate or components. The lower layer pads 130-1 may be multi-layer metals to have both low ohmic properties and strong mechanical properties.

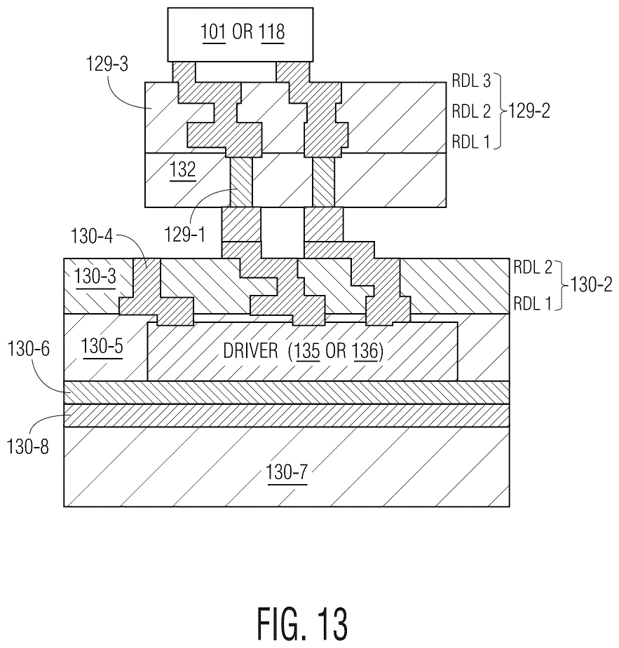

FIG. 13 shows an example of a multi-layer display where the upper and lower layers are integrated by an interconnect 129-7 that is formed between them. Micro-devices (micro-LEDs) 101 or 118 may be assembled on the upper layer before or after the two layers are integrated. An additional sacrificial layer 130-8 may be on the lower substrate 130-7 for the purpose of laser-liftoff or chemical liftoff of the driving IC layer film from substrate 130-7.

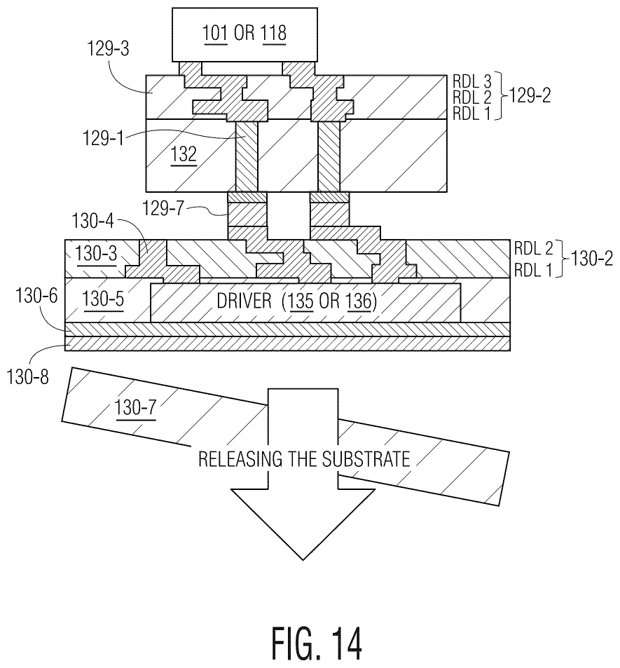

FIG. 14 shows an example of the process to release the lower substrate 130-7. A laser-liftoff process may be used for this step. For example, a sacrificial layer 130-8 that absorbs the laser is processed on the temporary substrate. The substrate release may be used to make a flexible display or to reduce the total weight of the display. Flexibility and weight reduction may be desirable when displays are being used in mobile devices and wearable devices.

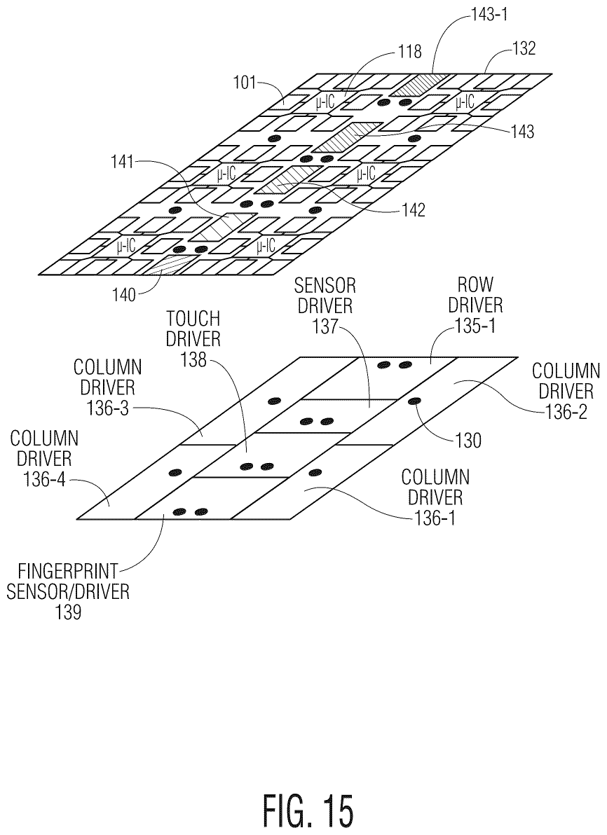

FIG. 15 shows an example of a multi-layer display where upper panel may have several active or passive elements such as sensors 140 and 141, camera 143-1, or emitters 142 and 143 at non-visible wavelengths. The upper layer and lower layer may be integrated using vias 129 and bonding pads 130. The positioning of the elements may be determined based on the placement of the LEDs (e.g. elements on the topside of the upper substrate are placed in vacant spots between the LEDs).

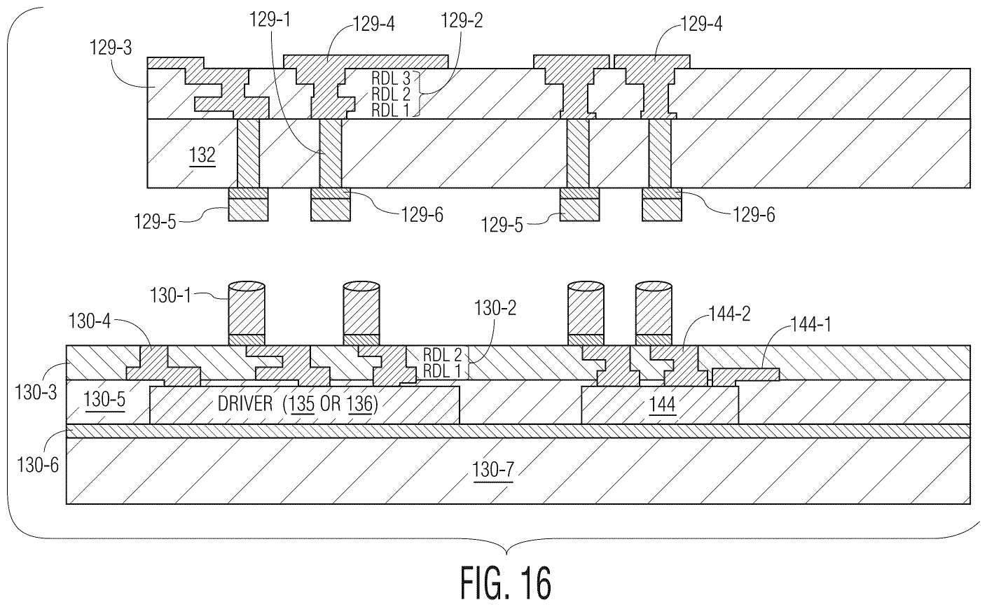

FIG. 16 shows an example of the structure for a multi-layer display during the alignment procedure. The new pads 129-4 for the sensors are connected to the lower layer using vias and bonding pads 144-2. The new driver 144 (e.g. for driving another device such as a sensor) is embedded in the resin 130-5 and RDL 144-1 distributes the signals between layers. Bonding electrodes 144-2 may be made with multi-layer metal or single-layer metal. The gap between the upper and lower panel may be filed with a polymer or a filler. It is noted that the bonding pads on both the upper and lower substrates are designed to properly align to ensure electrical connections of the devices on the upper substrate to the devices on the lower substrate.

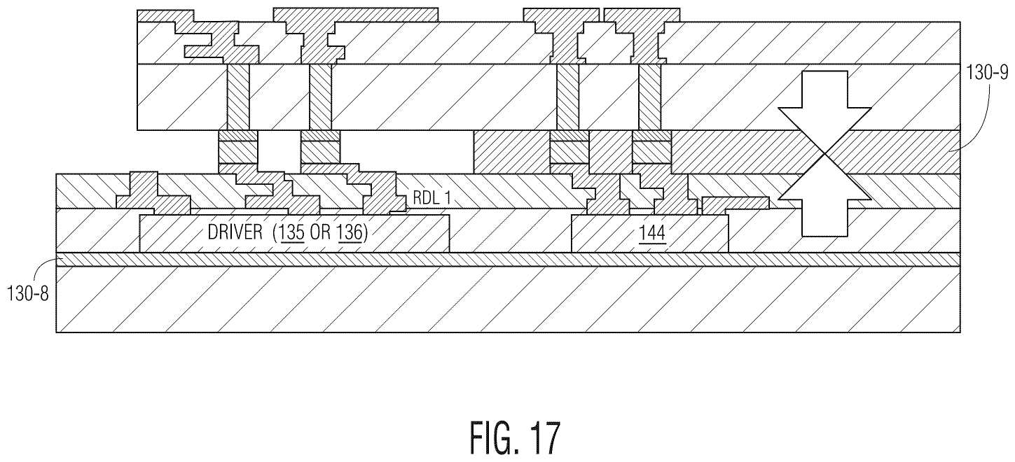

FIG. 17 shows an example of a multi-layer display with additional sensor pads after integration/bonding between the upper and lower panels. A sacrificial layer 130-8 may be on the carrier substrate to release the driving layer. This technique may be used to fabricate flexible displays to reduce overall device weight. The substrate integration can be used using a photo-definable or a soft polymer layer 130-9 that can be cured to provide extra mechanical strength.

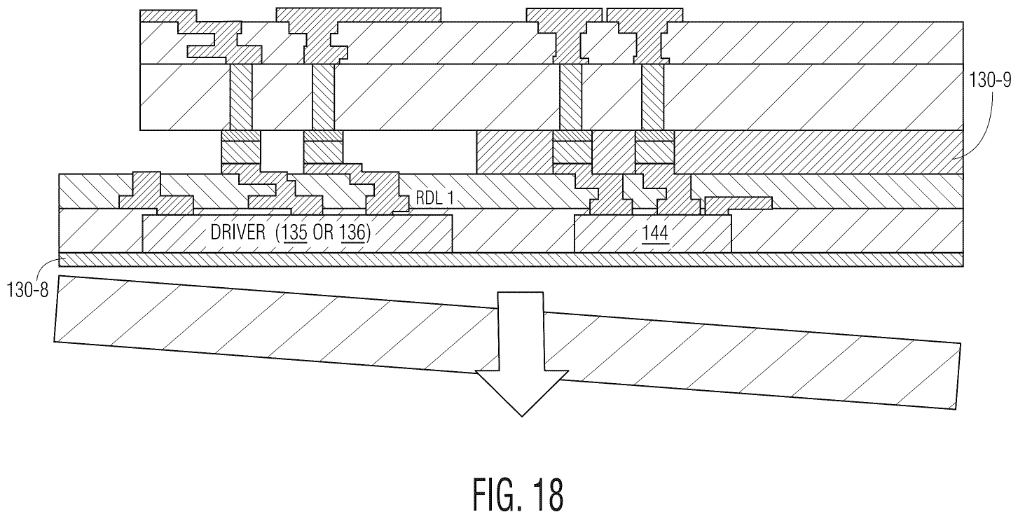

FIG. 18 shows an example of the process to release the lower (temporary) substrate 130-9. A laser-liftoff process may be used for this step. For example, a sacrificial layer 130-8 that absorbs the laser is processed on the temporary substrate. As already mentioned, the removal of the lower substrate may be beneficial for applications that require flexibility and/or weight reduction.

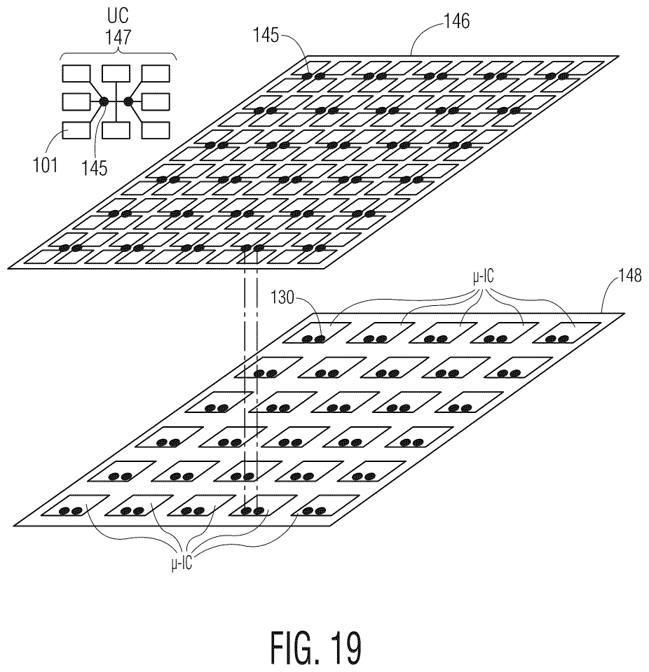

FIG. 19 shows an example of a multi-layer display where micro-LEDs (micro-devices) 101 and micro-ICs are integrated onto different layers. Micro-LEDs unit-cell (UC) 147 is made from a group of nearest micro-LEDs with connection to a group of vias 145. In one example, the upper panel 146 may only contain the micro-LEDs, vias and RDLs. In addition, the upper panel may be a bezel-free panel. In this example, the lower panel 148 may only contain micro-ICs 130 and RDLs. The UC vias 145 are aligned to the pads 130 on the panel with driving circuits. The row/column drivers might be embedded between micro-ICs or be integrated on the other side of the substrate using conductive through substrate vias.

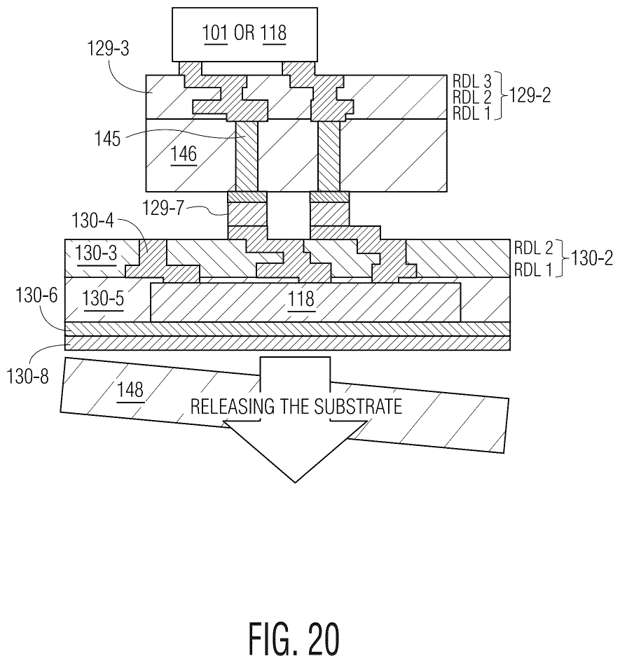

FIG. 20 shows an example of the process to remove the lower layer substrate 148. A laser-liftoff or chemical lift-off may be used to release the substrate. As a result, the driving circuit 118 mounted on a thin film may be transferred onto the upper substrate. One advantage of this method may be higher repairability and an easier test process by separating driving circuits (micro-ICs) and micro-LED integration processes onto two different substrates 146 and 148. In general, micro-ICs may be tested after transfer onto substrate 148 to detect the non-operational ICs and facilitate the repair process if needed.

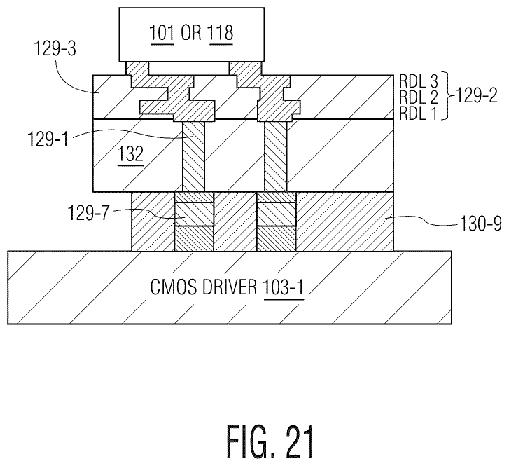

FIG. 21 shows an example of the structure where micro-LEDs (or other micro-devices such as laser diodes) are first integrated onto substrate 132 using conductive through vias 129-1. The substrate may be made from polymers, silicon, glass, ceramic or any other material that may provide desired optical, thermal, and mechanical properties. The micro-devices on substrate 132 may be connected to a CMOS driver substrate like a silicon substrate 135 using junction 129-7 that bond the vias to the CMOS pads. The bonding may be based on solder bonding, metal-to-metal bonding, or any other potential bonding technologies. The RDLs 129-2 may be used to rout the data and power on the upper layer. A dielectric may be used to passivate different RDL layers. As a result, several micro-devices may be first integrated on a substrate like ceramic or glass, and after the testing and validation, the whole package may be integrated on a CMOS driver in a single step. The CMOS driver may be capable of driving the micro-LEDs by modulation.

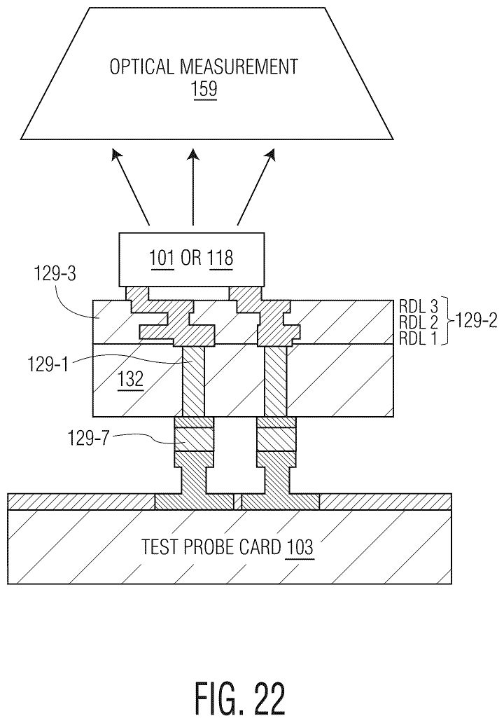

FIG. 22 shows an example of the testing structure for micro-LEDs (micro-devices) 101 or 118 after integration onto the substrate 132. The micro-devices 101 or 118 may be tested opto-electrically to validate their operation before integration onto the CMOS backplane. An optical measurement system 159 may be used to measure the spectrum, intensity, or operational frequency of the fabricated micro-devices 101 or 118. After the test, substrate 132, with micro-devices thereon, may be transferred, and be integrated onto a CMOS driver. In this testing method, a probe head or probe card 158 that may be active or passive may make temporary electrical contact 129-7 with the upper device layer. The temporary contact may be made with MEMS technology, socket technology or any other probe fabrication techniques. After applying voltages from the probe card 158 to micro-devices 101 or 108, both electrical and optical characteristics of the micro-devices may be measured and validated. The test probe card can test the LEDs through ON/OFF control and/or modulated control. This process ensures that the micro-devices are operational prior to integration with the CMOS driver.

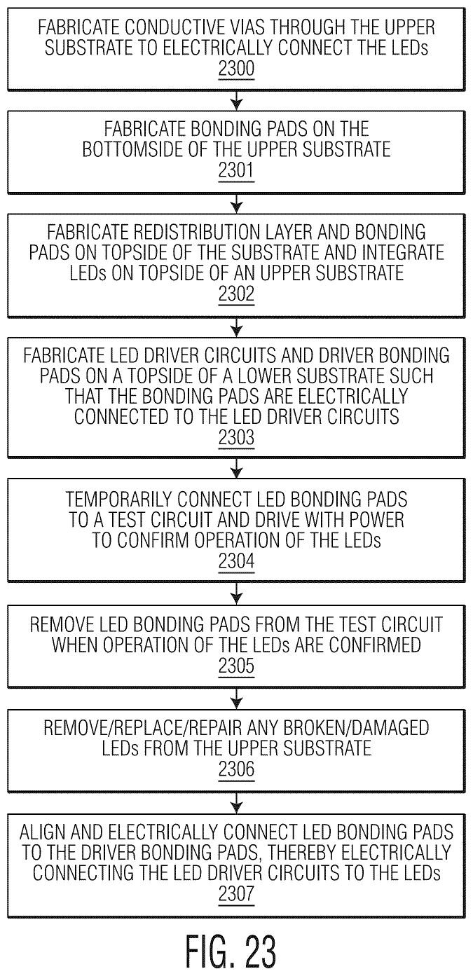

FIG. 23 shows a flowchart describing the manufacturing process of the micro-LED display. In step 2300, conductive vias are fabricated through the upper substrate. The conductive vias are being used to electrically connect LED bonding pads on the bottomside of the upper substrate to LED bonding pads on the topside of the upper substrate. In step 2301, the LED bonding pads are fabricated on the bottomside (e.g. backside) of the upper substrate. In step 2302, the metal layers to redistribute the power and/or data between the LED bonding pads are fabricated on the topside of the upper substrate and LEDs are integrated on the topside of the upper substrate. In step 2303, LED driver circuits and driver bonding pads are fabricated on a topside of a lower substrate such that the driver bonding pads are electrically connected to the LED driver circuits. It is noted that the order of steps 2300-2303 may be interchangeable. In step 2304, the LED bonding pads are temporarily connected to a test circuit and driven with power to confirm the operation of the LEDs. In step 2305, the LED bonding pads are removed from the test circuit when the operation of the LEDs is confirmed. In step 2306, broken LEDs may be removed or replaced with functional LEDs. In step 2307, the LED bonding pads are aligned and electrically connected to the driver bonding pads, thereby electrically connecting the LED driver circuits to the LEDs. It is noted that each of the steps may be performed by the same manufacturer or different manufacturers. For example, a first manufacturer can perform steps 2300-2306 to produce the LED display, whereas step 2307 may be performed by a second manufacturer that produces the lower driver substrate and then integrates the two devices (display substrate and driver substrate) to produce the final product.

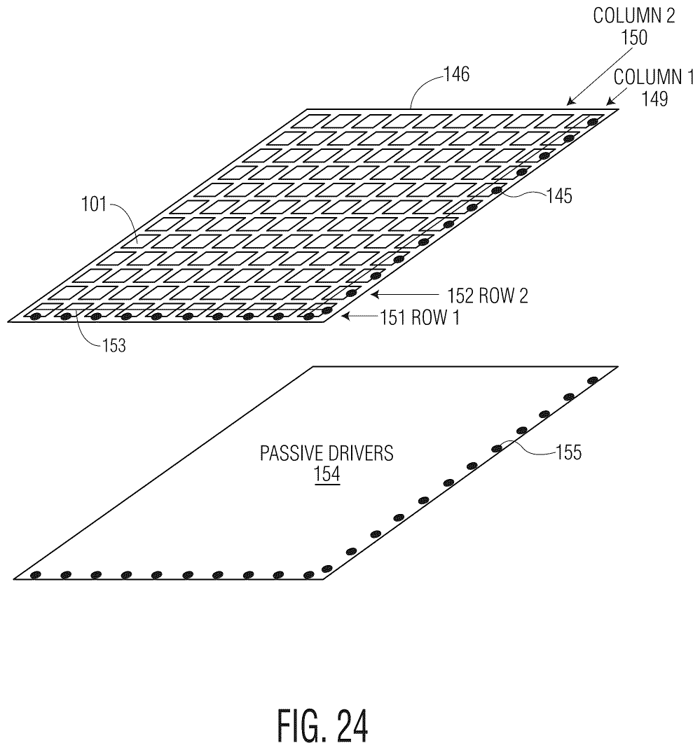

The previous figures depicted a micro-LED display device having upper/lower substrates with active drivers. FIG. 24 shows another example embodiment where a passive micro-LED display utilizes the fabrication process described above. For example, electrical lines for rows 151 and 152 and columns 149 and 152 are fabricated on the upper side substrate 146 which is a bezel-free structure, and the passive drivers 154 (e.g. RDL lines driven by external row/column drivers) are integrated onto the lower substrate 155. The passive driving electrical lines 153 connect micro-LEDs 101 to the vias located close to the substrate edge.

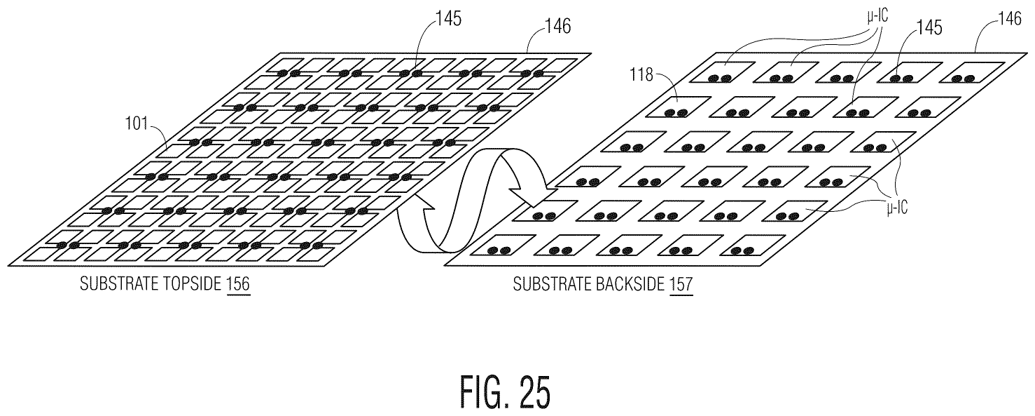

The previous figures depicted a micro-LED display device having two substrates that are separately manufactured and then integrated with one another. FIGS. 25-27 show another example embodiment where a single substrate is used to produce a micro-LED display device. In this example embodiment, both sides of a single substrate are utilized.

For example, FIG. 25 shows an example of a micro-LED display with micro-LEDs 101 integrated on the topside of the substrate 146 and driving micro-ICs 118 integrated on the backside of the same substrate 146. The devices on the topside and backside are electrically connected to each other using conductive through substrate vias 145. This may be considered a panel level integration of the micro-devices such as laser diodes or any other micro-devices on a topside of the panel. After populating the topside, the driving ICs 118 may be integrated on the back side to make electrical junctions using pads and vias. After assembling the micro-devices and micro-ICs, either side of the substrate may be coated with a resin to planarize the surface, perform heat extraction from the surface or generally to protect the device surface during handling. After full integration of micro-devices and micro-drivers, the panel (substrate) may then be diced into smaller sizes.

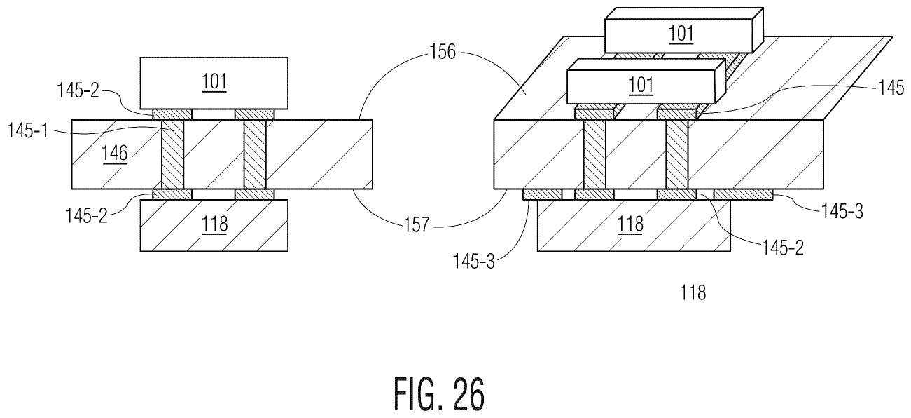

FIG. 26 shows an example of the double side panel level integration where the micro-devices 101 are integrated on panel topside 156 using bonding pads 145-2 and where micro-ICs 118 are connected to the panel backside (157) using bonding pads 145-2. The conductive through substrate via 145-1 connects the topside and backside of the panel 146. Several micro-devices 101 may be connected to one via 145-1 using metal lines. The power and data deliver lines 145-3 may also be used to route the power and data on the backside 157 or panel topside 156.

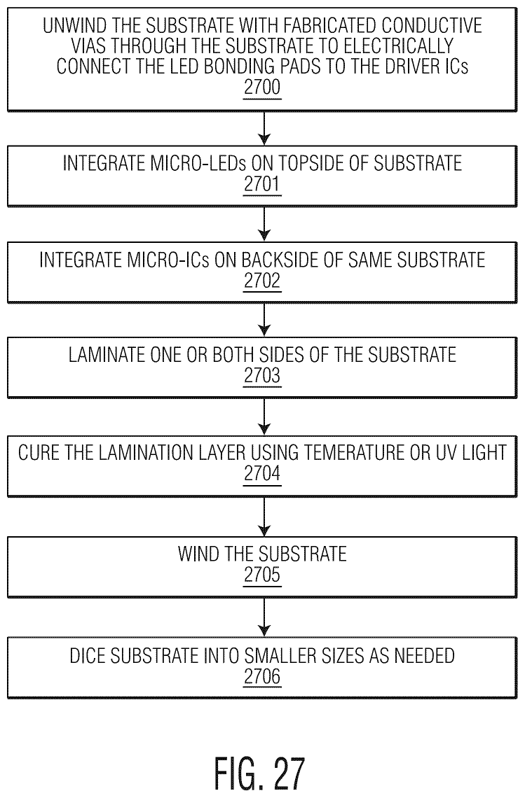

FIG. 27 shows a flowchart describing the manufacturing process of the micro-LED display with micro-LEDs integrated on the topside of the substrate and driving micro-ICs integrated on the backside (e.g. bottomside) of the same substrate, according to an example embodiment of the present disclosure. The manufacturing may be performed in a roll-to-roll process or on a flat substrate. In step 2700, the substrate can be unwind from a reel, or a flat substrate may be used. In addition, through substrate conductive vias are fabricated to connect LEDs on the upper side to the micro-ICs or other devices on the backside. In step 2701, the micro-LEDs are integrated on the topside of the substrate (e.g. connected to pads on the topside of the substrate). In step 2702, the micro-ICs 118 integrated on the backside of the same substrate (e.g. connected to pads on the bottomside of the substrate). It is noted that the order of steps 2701 and 2702 may be interchangeable. It is also noted that the micro-ICs on the topside and backside of the same substrate are electrically connected to each other using conductive through substrate vias connected to the respective pads. In step 2703, one or both sides of the substrate are coated/laminated with a resin to planarize the surface, perform heat extraction from the surface or generally to protect the device surface during handling. In step 2704, the substrate may go under thermal or UV curing to improve the coating layer performance. In step 2705, the substrate can be winded onto another reel or may be removed from the processing stage. In step 2706, after full integration of micro-devices and micro-drivers, the panel (substrate) is then diced into smaller sizes as desired (e.g. the entire panel substrate can be divided to produce smaller LED displays).

The disclosure includes a multi-layer display comprising an upper substrate including light emitting diodes (LEDs) fabricated on a topside of the upper substrate, and LED bonding pads fabricated on a bottomside of the upper substrate, the LED bonding pads being electrically connected to the LEDs through vias extending through the upper substrate, and a lower substrate including LED driver circuits and driver bonding pads fabricated on a topside of the lower substrate, the driver bonding pads being electrically connected to the LED driver circuits, wherein the LED bonding pads and driver bonding pads are aligned and electrically connected to each other, thereby electrically connecting the LED driver circuits to the LEDs.

The multi-layer display further comprising micro-integrated circuits (micro-ICs) fabricated on the topside of the upper substrate, the micro-ICs for driving the LEDs based on signals received from the LED driver circuits. The multi-layer display further comprising sensors fabricated on the topside of the upper substrate in between the LEDs. The multi-layer display wherein the lower substrate is releasable from the multi-layer display. The multi-layer display wherein the vias are arranged with respect to the LEDs in a manner to produce a bezel free multi-layer display.

The disclosure includes a method of manufacturing a multi-layer display, the method comprising fabricating light emitting diodes (LEDs) on a topside of an upper substrate, fabricating LED bonding pads on a bottomside of the upper substrate, fabricating vias through the upper substrate, the vias electrically connecting the LED bonding pads to the LEDs, fabricating LED driver circuits and driver bonding pads on a topside of a lower substrate, the driver bonding pads being electrically connected to the LED driver circuits, temporarily connecting the LED bonding pads to a test circuit and confirming operation of the LEDs, removing the LED bonding pads from the test circuit when operation of the LEDs are confirmed, and aligning and electrically connecting the LED bonding pads to the driver bonding pads, thereby electrically connecting the LED driver circuits to the LEDs.

The method of manufacturing a multi-layer display further comprising fabricating micro-integrated circuits (micro-ICs) on the topside of the upper substrate, the micro-ICs for driving the LEDs based on signals received from the LED driver circuits. The method of manufacturing a multi-layer display, further comprising fabricating sensors on the topside of the upper substrate in between the LEDs. The method of manufacturing a multi-layer display, further comprising releasing the lower substrate from the multi-layer display. The method of manufacturing a multi-layer display further comprising fabricating the vias with respect to the LEDs in a manner to produce a bezel free multi-layer display.

The disclosure includes a multi-layer display comprising an upper substrate including light emitting diodes (LEDs) fabricated on a topside of the upper substrate, and LED bonding pads fabricated on a bottomside of the upper substrate, and vias extending through the upper substrate and electrically connecting the LEDs to the LED bonding pads, wherein the LED bonding pads are aligned with driver bonding pads of a lower substrate including LED driver circuits, to facilitate electrical connection of LEDs to the LED driver circuits.

The multi-layer display, further comprising sensors on the topside of the upper substrate in between the LEDs. The multi-layer display, wherein the vias are arranged with respect to the LEDs in a manner to produce a bezel free multi-layer display.

The disclosure includes a method of manufacturing a multi-layer display, the method comprising fabricating light emitting diodes (LEDs) on a topside of an upper substrate, fabricating LED bonding pads on a bottomside of the upper substrate, and fabricating vias extending through the upper substrate and electrically connecting the LEDs to the LED bonding pads, wherein the LED bonding pads are fabricating to align with driver bonding pads of a lower substrate including LED driver circuits, to facilitate electrical connection of LEDs to the LED driver circuits.

The method of manufacturing a multi-layer display further comprising fabricating sensors on the topside of the upper substrate in between the LEDs. The method of manufacturing a multi-layer display, further comprising fabricating the vias with respect to the LEDs in a manner to produce a bezel free multi-layer display.

The disclosure includes a multi-layer display comprising a substrate including a topside and a bottomside opposite the topside, light emitting diodes (LEDs) fabricated on a topside of the substrate, LED driving circuits fabricated on a bottomside of the substrate, and through vias extending through the substrate and electrically connecting the LEDs to the driving circuits.

The multi-layer display, further comprising sensors on the topside of the upper substrate in between the LEDs. The multi-layer display, wherein the vias are arranged with respect to the LEDs in a manner to produce a bezel free multi-layer display.

The disclosure includes a method of manufacturing a multi-layer display, the method comprising fabricating light emitting diodes (LEDs) on a topside of the substrate, fabricating LED driving circuits on a bottomside of the substrate opposite the topside of the substrate, and fabricating through vias extending from the topside of the substrate to the bottomside of the substrate to electrically connect the LEDs to the driving circuits.

The method of manufacturing a multi-layer display, further comprising fabricating sensors on the topside of the upper substrate in between the LEDs. The method of manufacturing a multi-layer display, further comprising fabricating the vias with respect to the LEDs in a manner to produce a bezel free multi-layer display.

While the foregoing is directed to example embodiments described herein, other and further example embodiments may be devised without departing from the basic scope thereof. For example, aspects of the present disclosure may be implemented in hardware or software or a combination of hardware and software. One example embodiment described herein may be implemented as a program product for use with a computer system. The program(s) of the program product define functions of the example embodiments (including the methods described herein) and can be contained on a variety of computer-readable storage media. Illustrative computer-readable storage media include, but are not limited to: (i) non-writable storage media (e.g., read-only memory (ROM) devices within a computer, such as CD-ROM disks readably by a CD-ROM drive, flash memory, ROM chips, or any type of solid-state non-volatile memory) on which information is permanently stored; and (ii) writable storage media (e.g., floppy disks within a diskette drive or hard-disk drive or any type of solid state random-access memory) on which alterable information is stored. Such computer-readable storage media, when carrying computer-readable instructions that direct the functions of the disclosed example embodiments, are example embodiments of the present disclosure.

It will be appreciated to those skilled in the art that the preceding examples are exemplary and not limiting. It is intended that all permutations, enhancements, equivalents, and improvements thereto are apparent to those skilled in the art upon a reading of the specification and a study of the drawings are included within the true spirit and scope of the present disclosure. It is therefore intended that the following appended claims include all such modifications, permutations, and equivalents as fall within the true spirit and scope of these teachings.

What is claimed is:

1. A multi-layer display comprising:
an upper substrate including light emitting diodes (LEDs) fabricated on a topside of the upper substrate, and LED bonding pads fabricated on a bottomside of the upper substrate, the LED bonding pads being electrically connected to the LEDs through vias extending through the upper substrate; and
a lower substrate including LED driver circuits and driver bonding pads fabricated on a topside of the lower substrate, the driver bonding pads being electrically connected to the LED driver circuits,
wherein the LED bonding pads and driver bonding pads are aligned and electrically connected to each other, thereby electrically connecting the LED driver circuits to the LEDs.

2. The multi-layer display of claim 1, further comprising:
micro-integrated circuits (micro-ICs) fabricated on the topside of the upper substrate, the micro-ICs for driving the LEDs based on signals received from the LED driver circuits.

3. The multi-layer display of claim 1, further comprising:
sensors fabricated on the topside of the upper substrate in between the LEDs.

4. The multi-layer display of claim 1,
wherein the lower substrate is releasable from the multi-layer display.

5. The multi-layer display of claim 1,
wherein the vias are arranged with respect to the LEDs in a manner to produce a bezel free multi-layer display.

6. A method of manufacturing a multi-layer display, the method comprising:
fabricating light emitting diodes (LEDs) on a topside of an upper substrate;
fabricating LED bonding pads on a bottomside of the upper substrate;
fabricating vias through the upper substrate, the vias electrically connecting the LED bonding pads to the LEDs;
fabricating LED driver circuits and driver bonding pads on a topside of a lower substrate, the driver bonding pads being electrically connected to the LED driver circuits;
temporarily connecting the LED bonding pads to a test circuit and confirming operation of the LEDs;
removing the LED bonding pads from the test circuit when operation of the LEDs are confirmed; and
aligning and electrically connecting the LED bonding pads to the driver bonding pads, thereby electrically connecting the LED driver circuits to the LEDs.

7. The method of manufacturing a multi-layer display of claim 6, further comprising:
fabricating micro-integrated circuits (micro-ICs) on the topside of the upper substrate, the micro-ICs for driving the LEDs based on signals received from the LED driver circuits.

8. The method of manufacturing a multi-layer display of claim 6, further comprising:
fabricating sensors on the topside of the upper substrate in between the LEDs.

9. The method of manufacturing a multi-layer display of claim 6, further comprising:
releasing the lower substrate from the multi-layer display.

10. The method of manufacturing a multi-layer display of claim 6, further comprising:
fabricating the vias with respect to the LEDs in a manner to produce a bezel free multi-layer display.

11. A multi-layer display comprising:
an upper substrate including light emitting diodes (LEDs) fabricated on a topside of the upper substrate, and LED bonding pads fabricated on a bottomside of the upper substrate; and
vias extending through the upper substrate and electrically connecting the LEDs to the LED bonding pads,
wherein the LED bonding pads are aligned with driver bonding pads of a lower substrate including LED driver circuits, to facilitate electrical connection of LEDs to the LED driver circuits.

12. The multi-layer display of claim 11, further comprising:
sensors on the topside of the upper substrate in between the LEDs.

13. The multi-layer display of claim 11,
wherein the vias are arranged with respect to the LEDs in a manner to produce a bezel free multi-layer display.

14. A method of manufacturing a multi-layer display, the method comprising:
fabricating light emitting diodes (LEDs) on a topside of an upper substrate;
fabricating LED bonding pads on a bottomside of the upper substrate; and
fabricating vias extending through the upper substrate and electrically connecting the LEDs to the LED bonding pads,
wherein the LED bonding pads are fabricating to align with driver bonding pads of a lower substrate including LED driver circuits, to facilitate electrical connection of LEDs to the LED driver circuits.

15. The method of manufacturing a multi-layer display of claim 14, further comprising:
fabricating sensors on the topside of the upper substrate in between the LEDs.

16. The method of manufacturing a multi-layer display of claim 14, further comprising:
fabricating the vias with respect to the LEDs in a manner to produce a bezel free multi-layer display.

17. A multi-layer display comprising:
a substrate including a topside and a bottomside opposite the topside;
light emitting diodes (LEDs) fabricated on a topside of the substrate;
LED driving circuits fabricated on a bottomside of the substrate; and
through vias extending through the substrate and electrically connecting the LEDs to the driving circuits.

18. The multi-layer display of claim 17, further comprising:
sensors on the topside of the upper substrate in between the LEDs.

19. The multi-layer display of claim 17,
wherein the vias are arranged with respect to the LEDs in a manner to produce a bezel free multi-layer display.

20. A method of manufacturing a multi-layer display, the method comprising:
fabricating light emitting diodes (LEDs) on a topside of the substrate;
fabricating LED driving circuits on a bottomside of the substrate opposite the topside of the substrate; and
fabricating through vias extending from the topside of the substrate to the bottomside of the substrate to electrically connect the LEDs to the driving circuits.

21. The method of manufacturing a multi-layer display of claim 20, further comprising:
fabricating sensors on the topside of the upper substrate in between the LEDs.

22. The method of manufacturing a multi-layer display of claim 20, further comprising:
fabricating the vias with respect to the LEDs in a manner to produce a bezel free multi-layer display.
